(19) United States
(12) Patent Application Publication
(10) Pub. No.: US 2004/0262608 A1
(43) Pub. Date: Dec. 30, 2004

(54) Design for thin film transistor to improve mobility

(76) Inventors: Hoon Kim, Seocho-gu (KR); Ki-Yong Lee, Yongin-si (KR); Jin-Wook Seo, Suwon-si (KR)

Correspondence Address: Robert E. Bushnell, Suite 300, 1522 K Street, N.W., Washington, DC, 20005-1202, US

(21) Appl. No.: 10/866,735

(22) Filed: Jun. 15, 2004

(30) Foreign Application Priority Data
Jun. 25, 2003 (KR) 2003-41751

(51) Int. Cl. H01L 29/76

(52) U.S. Cl. 257/66

(57) ABSTRACT

A thin film transistor having a semiconductor layer arranged on a substrate, a gate insulation layer arranged on the substrate and on a semiconductor layer, and a gate arranged on the gate insulation layer, the gate insulation layer arranged to have a thickness from equal to a thickness of the semiconductor layer to 1.5 times of thickness of the semiconductor layer. The gate insulation layer can be a nitride film only, an oxide film only, or a laminated film made up of both nitride layers and oxide layers. The thin film transistor can be incorporated into a design for a flat panel display.

### CLAIM OF PRIORITY

This application makes reference to, incorporates the same herein, and claims all benefits accruing under 35 U.S.C. §119 from an application for THIN FILM TRANSISTOR earlier filed in the Korean Intellectual Property Office on 25 Jun. 2003 and there duly assigned Serial No. 2003-41751.

### BACKGROUND OF THE INVENTION

1. Field of the invention

The present invention relates to a novel design for a thin film transistor (or TFT) that maximizes the mobility in the semiconductive layer.

2. Description of Related Art

In thin film transistors used in flat panel display devices, if the thickness of polysilicon film used as a semiconductor layer is decreased, the mobility is increased due to the improved crystallization characteristics, and it is possible to decrease the thickness of the gate insulation film (or gate oxide film) so that the threshold voltage of the thin film transistor may be decreased.

As the thickness of gate insulation film is decreased, the electrical characteristics, for example, threshold voltage (or Vₜₕ) characteristics are improved. However, there is a disadvantage in that decreasing the thickness of the gate insulation film also can causes breakage of the device due to breakdown. On the other hand, there have been problems in that mobility is decreased and the Vₜₕ is increased when the thickness of the gate insulation film is increased.

A technology for increasing carrier mobility in a channel layer under gate insulation film is disclosed in Korean Patent No. 10-0267491. In order to increase mobility in a channel layer of a semiconductor layer, the gate oxide film is formed on the pretreated surface of the silicon substrate, following pretreating the surface of silicon substrate to reduce the surface roughness of the silicon substrate. Furthermore, a technology for increasing mobility by forming gate oxide film on the tilted step after forming a step tilted to an angle of 4 degrees on silicon substrate is disclosed in Korean Patent Publication No. 2000-0025409.

Thus, the above documents relate to methods for increasing mobility by pretreating a silicon substrate or increasing mobility by forming step on the silicon substrate before forming gate oxide film in semiconductor device. However, a technology capable of preventing breakage of the TFT as maintaining characteristics of mobility and threshold voltage values of the TFT when forming gate insulation film on semiconductor layer formed of polysilicon film like thin film transistor TFTs in flat panel display devices is not suggested in these documents. Therefore, what is needed is a method of making and a design for a TFT that results in a TFT with good mobility characteristics and good threshold voltage characteristics while maintaining good electrical characteristics.

### SUMMARY OF THE INVENTION

It is therefore an object of the present invention to provide an improved thin film transistor design.

It is also an object of the present invention to provide a method of making a thin film transistor that produces a thin film transistor having good mobility while not having voltage breakdown.

It is further an object of the present invention to provide an improved design for a thin film transistor by controlling a ratio of thicknesses of the of gate insulation film to the thickness of the polysilicon active layer.

It is another object of the present invention to provide a thin film transistor having improved electrical characteristics without device quality deterioration.

These and other objects can be achieved by a thin film transistor having a semiconductor layer formed on a substrate, a gate insulation film formed over the substrate and over the semiconductor layer and a gate formed on the gate insulation film on the upper part of the semiconductor layer, where the ratio of the thickness of the gate insulation film to the thickness of the semiconductor layer is between 1.0 to 1.5. Preferably, the semiconductor layer including the channel layer is crystalized polysilicon and is subjected to an HF pretreatment resulting to further improved mobility. Preferably, the novel thin film transistor is part of a flat panel display device structure.

The flat panel display device further comprises a third insulation film formed between a lower electrode as the pixel electrode and the source/drain electrode and including a via hole for connecting the pixel electrode to one of the source/drain electrodes, an organic thin film layer formed on the lower electrode, and an upper electrode formed on the organic thin film layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross sectional view of a thin film transistor according to preferred embodiment of the present invention;

FIG. 2 is a graph empirically illustrating a mobility in a TFT versus the ratio of the thicknesses of the gate insulation film to the polysilicon film for cases where the polysilicon is pretreated by HF and where the polysilicon film is not pretreated; and

FIG. 3 illustrates a cross section view of flat panel display device using the novel thin film transistor of FIG. 1 according to a preferred embodiment of the present invention.

### DETAILED DESCRIPTION OF THE INVENTION

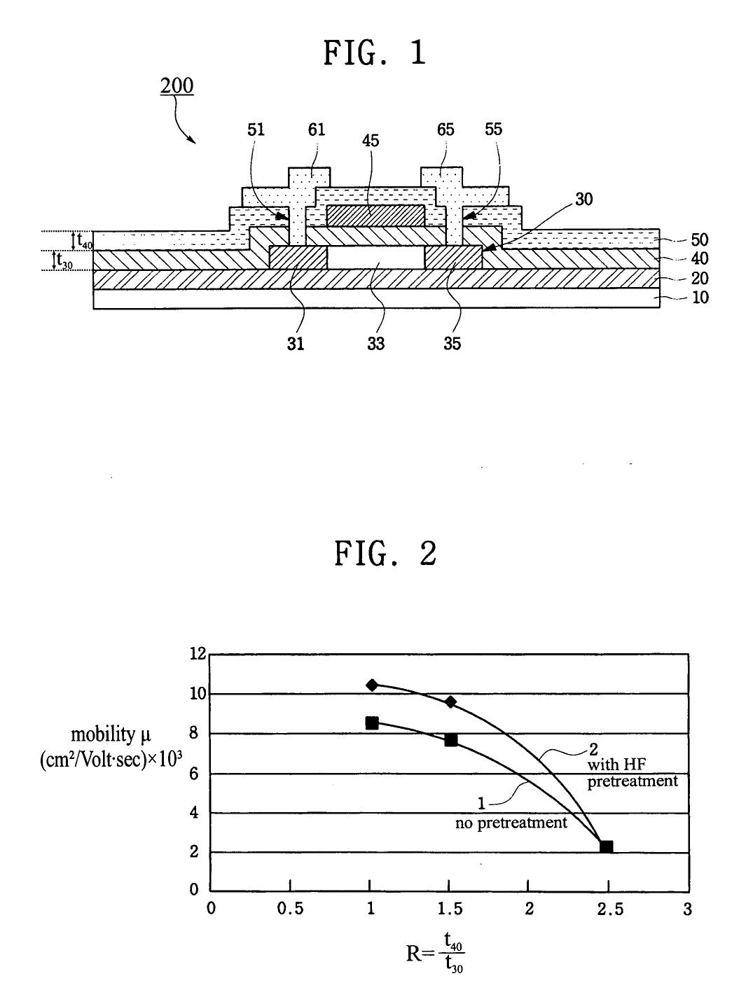

Turning now to the figures, FIG. 1 illustrates a cross section view of thin film transistor 200 for flat panel display device according to a preferred embodiment of the present invention. Referring to FIG. 1, a buffer layer 20 is formed on an insulation substrate 10, and a semiconductor layer 30 made of polysilicon film is formed on the buffer layer 20. The semiconductor layer 30 includes source/drain regions 31 and 35 which are doped with high concentration impurities having a P or N type conductivity. A portion of the semiconductor layer 30 between the source/drain regions 31 and 35 is a channel layer 33 which is an intrinsic region. A gate insulation film 40 is formed on the buffer layer 20 and on top of the semiconductor layer 30, and a gate 45 is formed on the gate insulation film 40 over the channel layer 33 of the semiconductor layer 30. As illustrated in FIG. 1, gate insulation film 40 has a thickness t₄₀ and semiconductor layer 30 has a thickness t₃₀.

After formation of the semiconductor layer 30 and the gate insulation film 40, a gate layer 45 is formed on the gate insulation film 40. Then, an interlayer insulation film 50 is formed on the gate insulation film 40 and on the gate 45. Interlayer insulation film 50 is perforated by contact holes 51 and 55 exposing the doped source/drain regions 31 and 35 respectively of semiconductor layer 30. Contact holes 51 and 55 are formed by etching the interlayer insulation film 50. Source/drain electrodes 61 and 65 are formed in contact holes 51 and 55 respectively to electrically connected to the source/drain regions 31 and 35 respectively through the contact holes 51 and 55, respectively.

Turning now to FIG. 2, FIG. 2 illustrates empirical results of measured mobility in the TFT of FIG. 1 versus the ratio R of the thickness t₄₀ of the gate insulation film to the thickness t₃₀ of the semiconductor layer. In FIG. 2, two lines are illustrated. The first line (line 1) in FIG. 2 illustrates the measured mobility μ versus the thickness ratio R when no pretreatment process is carried out on the semiconductor layer after the deposition and patterning of the semiconductor layer and after the crystallizing the silicon film. The second line (line 2) in FIG. 2 illustrates the measured mobility μ versus the thickness ratio R when the patterned semiconductor layer 30 is subjected to an HF pretreatment.

Referring to FIG. 2, it is clear that the mobility is greatest when the t₄₀ to t₃₀ ratio R is in the preferred range of 1.0 to 1.5. Expressed as an inequality, the ratio R=t₄₀/t₃₀ preferably satisfies the inequality 1.0≦R≦1.5. In this 1.0 to 1.5 range, the mobility varies little within this range and the mobility in this range is essentially saturated. In addition, in this preferred 1.0 to 1.5 range, the mobility is higher when the polysilicon is pretreated with HF than when no pretreatment occurs. When the ratio of the thicknesses of t₄₀ to t₃₀ exceeds 1.5 and is thus outside the preferred range, the mobility falls off sharply as illustrated empirically in FIG. 2. At the other extreme, when the thickness t₄₀ of the gate insulation film 40 is less than the thickness t₃₀ of the polysilicon film of the semiconductor layer 30, the uniformity of film thickness t₄₀ of the gate insulation film 40 is deteriorated. In particular, a protrusion part generated during crystallization of the polysilicon film using laser is exposed, and failure is caused during TFT fabrication process accordingly if thickness t₄₀ of the gate insulation film 40 is less than thickness of the polysilicon film t₃₀. For this reason, it is not preferable to make the TFT where the ratio R of t₄₀ to t₃₀ is less than 1.0.

The gate insulation film 40 is formed of gate insulation material such as oxide film or nitride film in a single layer structure or formed of the oxide film and nitride film in a laminated layer structure, and the polysilicon film is formed using an ordinary crystallization method such as solid phase crystallization method or laser crystallization method.

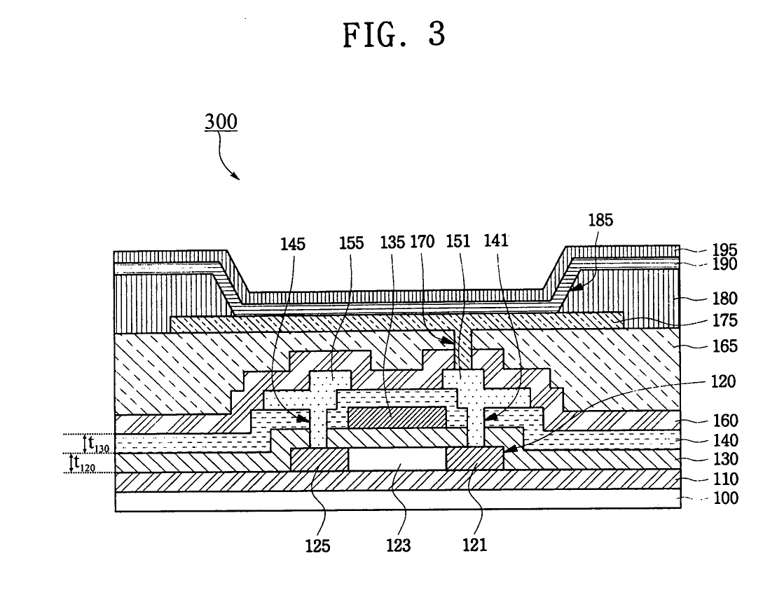

Turning now to FIG. 3, FIG. 3 illustrates a cross section view of flat panel display device 300 using a thin film transistor according to a preferred embodiment of the present invention. The TFT used in flat panel display 300 may be the same as TFT 200 of FIG. 1 but this invention is not limited thereto. Referring to FIG. 3, a buffer layer 110 is formed on an insulation substrate 100, and a semiconductor layer 120 is formed on the buffer layer 110. The semiconductor layer 120 includes source/drain regions 125 and 121 which are doped with high concentration impurities having a P or N type conductivity. A portion of the semiconductor layer 120 between the source/drain regions 121 and 125 is a channel layer 123 remains intrinsic and is not doped. A gate insulation film 130 is formed on the buffer layer 110 and on the semiconductor layer 120, and a gate 135 is formed on the gate insulation film (or gate insulation layer) 130 over the intrinsic channel layer 123 of the semiconductor layer 120.

The semiconductor layer 120 includes polysilicon film crystallized through a crystallization method. The gate insulation film 130 includes one of a single-layered film of silicon oxide or silicon nitride and a multi-layered film of silicon oxide and silicon nitride. The gate insulation film 130 is preferably formed to has a thickness t₁₃₀ between 1.0 and 1.5 times a thickness t₁₂₀ of the semiconductor layer 120 to boost the mobility in the semiconductor layer 120. Then, an interlayer insulation film 140 is formed on the gate insulation film 130 and on the gate 135. Interlayer insulation film 140 is perforated by contact holes 141 and 145 respectively to expose source/drain regions 121 and 125 respectively of semiconductor layer 120. Contact holes 141 and 145 respectively are filled in by source/drain electrodes 155 and 151 respectively. Source/drain electrodes 151 and 155 respectively form electrical contact with source/drain regions 121 and 125 respectively on semiconductor layer 120.

A passivation layer 160 and a planarization layer 165 are formed over the substrate and include a via hole 170 exposing a portion of one of the source/drain electrodes 151 and 155 (drain electrode 155 illustrated in FIG. 3). A lower electrode 175 is formed on the planarization layer 165 and fills via hole 170 to form electrical contact with source/drain electrode 151 and 155 (151 illustrated in FIG. 3). A pixel defining layer 180 having an opening 185 for exposing the lower electrode 175 is formed over the substrate and an organic thin film layer 190 and an upper electrode 195 are formed on the lower electrode 175 and the pixel defining layer 180. Therefore, organic electroluminescence (EL) device including the lower electrode 175, the organic thin film layer 190 and the upper electrode 195 is fabricated and forms electrical contact to the underlying TFT.

Preferably, the lower electrode 175 is made out of a light reflective material and preferably the upper electrode 195 is made out of an optically transmissive material to allow light generated in the film layer 190 to escape from the top of the device through upper electrode 195. The organic thin film layer 190 can be made out of a hole injection layer, a hole transport layer, an organic light emitting layer, a hole barrier layer, an electron transport layer or an electron injection layer.

As described in the above, a thin film transistor according to preferred embodiments of the present invention has merits in that the thin film transistor not only optimizes mobility, but also improves characteristics of device and prevents failure of the device by optimizing thickness of the gate insulation film in relation to the thickness of the polysilicon film.

While the invention has been particularly shown and described with reference to preferred embodiments thereof, it will be understood by those skilled in the art that the foregoing and other changes in form and details may be made therein without departing from the spirit and scope of the invention.

What is claimed is:

1. A thin film transistor, comprising:
a semiconductor layer arranged on a substrate;
a gate insulation layer arranged on the substrate and on the semiconductor layer; and
a gate arranged on the gate insulation layer on the semiconductor layer, wherein a thickness of the gate insulation layer is at least a thickness of the semiconductor layer.

2. The thin film transistor of claim 1, the gate insulation layer being selected from the group consisting of a nitride layer only, an oxide layer only and a laminated layer comprising both a nitride layer and an oxide layer.

3. The thin film transistor of claim 1, wherein the semiconductor layer is an HF cleaned polysilicon layer.

4. The thin film transistor of claim 1, further comprising:
an interlayer insulation layer arranged over the substrate and being perforated by contact holes exposing portions of the semiconductor layer; and
a source/drain electrodes arranged on the interlayer insulation layer and filling the contact holes to form contact with the semiconductor layer.

5. A thin film transistor, comprising:
a semiconductor layer arranged on a substrate;
a gate insulation layer arranged on the substrate and on the semiconductor layer; and
a gate arranged on the gate insulation layer and over the semiconductor layer, wherein the gate insulation layer has a thickness not more than 1.5 times a thickness of the semiconductor layer.

6. The thin film transistor of claim 5, the gate insulation layer being selected from the group consisting of a nitride layer only, an oxide layer only and a laminated layer comprising both a nitride layer and an oxide layer.

7. The thin film transistor of claim 5, wherein the semiconductor layer is an HF cleaned polysilicon layer.

8. The thin film transistor of claim 5, further comprising:
an interlayer insulation layer arranged over the substrate and being perforated by contact holes exposing portions of the semiconductor layer; and
a source/drain electrodes arranged on the interlayer insulation layer and filling the contact holes to form contact with the semiconductor layer.

9. A thin film transistor, comprising:
a semiconductor layer arranged on a substrate;
a gate insulation layer arranged on the substrate and on the semiconductor layer; and
a gate arranged on the gate insulation layer and over the semiconductor layer, wherein a thickness of the gate insulation layer being at least a thickness of the semiconductor layer and being no more than 1.5 times the thickness of the semiconductor layer.

10. The thin film transistor of claim 9, the gate insulation layer being selected from the group consisting of a nitride layer only, an oxide layer only and a laminated layer comprising both a nitride layer and an oxide layer.

11. The thin film transistor of claim 9, wherein the semiconductor layer is an HF cleaned polysilicon layer.

12. The thin film transistor of claim 9, further comprising:
an interlayer insulation layer arranged over the substrate and being perforated by contact holes exposing portions of the semiconductor layer; and
a source/drain electrodes arranged on the interlayer insulation layer and filling the contact holes to form contact with the semiconductor layer.

13. A thin film transistor, comprising:
a semiconductor layer arranged on a substrate;
a gate insulation layer arranged on the substrate and on the semiconductor layer;
a gate arranged on the gate insulation layer over the semiconductor layer;
an interlayer insulation layer arranged over the substrate and being perforated by contact holes exposing portions of the semiconductor layer; and
source/drain electrodes arranged on the interlayer insulation layer and arranged in the contact holes to contact the semiconductor layer through contact holes, respectively, wherein a thickness of the gate insulation layer is dependent on a thickness of the semiconductor layer.

14. The thin film transistor of claim 13, the thickness of the gate insulation layer is at least as large as the thickness of the semiconductor layer.

15. The thin film transistor of claim 13, the thickness of the gate insulation layer is no more than 1.5 times the thickness of the semiconductor layer.

16. The thin film transistor of claim 13, the thickness of the gate insulation layer being between 1.0 and 1.5 times the thickness of the semiconductor layer.

17. The thin film transistor of claim 13, the gate insulation layer being selected from the group consisting of a nitride layer only, an oxide layer only and a laminated layer comprising both a nitride layer and an oxide layer.

18. A flat panel display device, comprising:
a semiconductor layer arranged on a substrate;
a first insulation layer arranged on the substrate and on the semiconductor layer;
a gate arranged on the gate insulation layer over the semiconductor layer;
a second insulation layer arranged over the substrate, the second insulating layer being perforated by contact holes exposing portions of the semiconductor layer;
source/drain electrodes arranged on the second insulation layer, the source/drain electrodes filling the contact holes to contact the semiconductor layer; and
a pixel electrode connected to one of the source/drain electrodes, wherein a thickness of the first insulation layer is at least 1.0 and no more than 1.5 times a thickness of the semiconductor layer.

19. The flat panel display device of claim 18, wherein the gate insulation layer being selected from the group consisting of a nitride layer only, an oxide layer only and a laminated layer comprising both a nitride layer and an oxide layer and the semiconductor layer comprising polysilicon.

20. The flat panel display device of claim 18, further comprising:
a third insulation layer arranged between a lower pixel electrode and the source/drain electrode, the third insulating layer being perforated by a via hole, the via hole being filled with a conductor to connect the lower pixel electrode to the one of the source/drain electrodes;
an organic thin layer arranged on the lower pixel electrode; and
an upper pixel electrode arranged on the organic thin layer.

21. The flat panel display device of claim 20, the lower pixel electrode being optically reflective and the upper pixel electrode being optically transparent.

22. The flat panel display device of claim 18, the semiconductor layer comprising an HF cleaned polysilicon.
